(19) United States
(12) Patent Application Publication
(10) Pub. No.: US 2012/0190200 A1
(43) Pub. Date: Jul. 26, 2012

(54) Abrasive Free Silicon Chemical Mechanical Planarization

(75) Inventors: Naresh K. Penta, Newark, DE (US); Suryadevara V. Babu, Potsdam, NY (US)

(73) Assignee: CLARKSON UNIVERSITY, Potsdam, NY (US)

(21) Appl. No.: 13/356,980

(22) Filed: Jan. 24, 2012

Related U.S. Application Data
(60) Provisional application No. 61/457,182, filed on Jan. 24, 2011.

(51) Int. Cl. H01L 21/306; C09K 13/00; H01L 21/304

(52) U.S. Cl. 438/692; 252/79.1; 257/E21.23

(57) ABSTRACT

A chemical mechanical planarization method uses a chemical mechanical planarization composition that includes at least one nitrogen containing material and a pH modifying material, absent an abrasive material. The nitrogen containing material may be selected from a particular group of nitrogen containing polymers and corresponding nitrogen containing monomers. The chemical mechanical planarization method and the chemical mechanical planarization composition provide for planarizing a silicon material layer, such as but not limited to a poly-Si layer, in the presence of a silicon containing dielectric material layer, such as but not limited to a silicon oxide layer or a silicon nitride layer, with enhanced efficiency provided by an enhanced removal rate ratio.

### CROSS-REFERENCE TO RELATED APPLICATION

This application is related to, and derives priority from, U.S. Provisional Patent Application Ser. No. 61/457,182, filed 24 Jan. 2011 and titled “Abrasive Free Slurries for Selective Polishing of Polysilicon over Silicon Dioxide and Silicon Nitride Films,” the contents of which are incorporated herein fully by reference.

### STATEMENT OF GOVERNMENT INTEREST

The research described herein is based upon work supported in part by the U.S. Army Research Office under contract number W911NF-05-1-0339. The U.S. Government has rights in the invention disclosed and claimed herein.

### BACKGROUND OF THE INVENTION

1. Field of the Invention

Embodiments relate generally to chemical mechanical planarization (CMP) processing. More particularly embodiments relate to enhanced chemical mechanical planarization (CMP) processing of silicon material layers.

2. Description of the Related Art

Polysilicon (poly-Si) is often used as a part of a gate electrode in 3D nonplanar Fin field-effect-transistor (FinFET) structures that are proposed to replace the classical planar single gate metal oxide-semiconductor field effect transistors (MOSFETs) for reducing short channel effects and to facilitate further scaling. Poly-Si is also used as a floating gate in NAND flash memory cells, as a sacrificial layer in metal gate replacement techniques during the fabrication of a high-K metal gate MOSFET device and as a structural element for movable parts in microelectromechanical systems (MEMS).

During the fabrication of FinFET, NAND flash memory and MEMS devices one of the major challenges is to achieve local and global planarization by removing a large step height of poly-Si layers. As it is well-known, a particularly viable technique for this purpose is chemical mechanical planarization (CMP). During the CMP process, an overburden of poly-Si has to be selectively planarized over an underlying silicon oxide/silicon nitride pattern. This step typically requires a slurry which provides high poly-Si removal rates (RRs) and very low silicon oxide and silicon nitride RRs (˜1 nm/min or lower).

Since the planarization of topographic poly-Si layers and topographic poly-Si structures is likely to continue to be of importance in the microelectronic and microelectromechanical system processing and technology arts, desirable are additional methods and materials for effectively planarizing topographic poly-Si layers and topographic poly-Si structures in the presence of other material layers, and in particular in the presence of underlying silicon containing dielectric material layers such as but not limited to silicon oxide material layers, silicon nitride material layers, silicon carbide material layers and carbon and hydrogen doped silicon oxide material layers.

### SUMMARY

Non-limiting embodiments provide a chemical mechanical planarization (CMP) composition for planarizing a silicon material layer, such as but not limited to a poly-Si layer, in the presence of a silicon containing dielectric material layer, such as but not limited to a silicon oxide layer or a silicon nitride layer. Non-limiting embodiments also provide a chemical mechanical planarization (CMP) method for planarizing the silicon material layer, such as but not limited to the poly-Si layer, in the presence of the silicon containing dielectric material layer, such as but not limited to the silicon oxide layer or the silicon nitride layer. The chemical mechanical planarization (CMP) composition which is used in the chemical mechanical planarization (CMP) method in accordance with the non-limiting embodiments uses a pH adjusted aqueous solution of at least one nitrogen containing polymer (or corresponding monomer), which may be selected from a particular non-limiting group of nitrogen containing polymers (and corresponding monomers), absent an abrasive material, such as but not limited to a silicon oxide abrasive material or a cerium oxide abrasive material.

Particular non-limiting examples of nitrogen containing polymers within the particular group of nitrogen containing polymers include, but are not limited to: (1) poly(diallyldimethylammonium chloride) (PDADMAC); (2) poly(dimethylamine-co-epichlorohydrin-co-ethylenediamine) (PDEE); (3) poly(allylamine) (PAAm); (4) poly(ethylene imine) (PEI); (5) poly(acrylamide) (PAA); and (6) poly(acrylamide-co-diallydimethyl ammonium chloride) (PAA-DADMAC). Corresponding nitrogen containing monomers include: (1) diallyldimethylammonium chloride; (2) allylamine; and (3) acrylamide.

Thus, the foregoing nitrogen containing polymers and corresponding nitrogen containing monomers include ammonium, amine and amide chemical functionality. Of the foregoing, PDADMAC, PDEE, PAAm and PEI, and their corresponding monomers diallyldimethylammonium chloride and allylamine, show particular promise for providing enhanced RRs of silicon material layers, such as but not limited to poly-Si material layers, in the presence of silicon containing dielectric material layers, such as but not limited to silicon oxide material layers and silicon nitride material layers.

A particular chemical mechanical planarization composition in accordance with the embodiments includes an aqueous solution comprising at least one nitrogen containing material selected from the group consisting of poly(diallyldimethylammonium chloride) (PDADMAC), poly(dimethylamine-co-epichlorohydrin-co-ethylenediamine) (PDEE), poly(allylamine) (PAAm) and poly(ethylene imine) (PEI), poly(acrylamide) (PAA) and poly(acrylamide-co-diallydimethyl ammonium chloride) (PAA-DADMAC) nitrogen containing polymers, and diallyldimethylammonium chloride, allylamine and acrylamide nitrogen containing monomers, at a concentration from about 5 to about 1000 ppm by weight. This particular chemical mechanical planarization composition also includes a pH adjusting material, absent an abrasive material.

A particular chemical mechanical planarization method in accordance with the embodiments includes positioning a within a chemical mechanical planarization apparatus a substrate including a silicon material layer located over a silicon containing dielectric material layer. This particular method also includes planarizing within the chemical mechanical planarization apparatus the silicon material layer with respect to the silicon containing dielectric material layer while using a chemical mechanical planarization pad and a chemical mechanical planarization composition comprising: (1) an aqueous solution comprising at least one nitrogen containing material; and (2) a pH adjusting material, absent an abrasive material.

Another particular chemical mechanical planarization method in accordance with the embodiments includes positioning a within a chemical mechanical planarization apparatus a substrate including a polysilicon material layer located over at least one of a silicon oxide layer and a silicon nitride layer. This other particular method also includes planarizing within the chemical mechanical planarization apparatus the polysilicon material layer with respect to the at least one of the silicon oxide layer and the silicon nitride layer while using a chemical mechanical planarization pad and a chemical mechanical planarization composition comprising: (1) an aqueous solution comprising at least one nitrogen containing material; and (2) a pH adjusting material, absent an abrasive material.

### BRIEF DESCRIPTION OF THE DRAWINGS

The objects, features and advantages of the embodiments are understood within the context of the Detailed Description of the Embodiments, as set forth below. The Detailed Description of the Embodiments is understood within the context of the accompanying drawings, which form a material part of this disclosure, wherein:

FIG. 1 shows a series of chemical structures of nitrogen containing polymer materials (i.e., polyelectrolytes) that may be used in accordance with the embodiments. Particular nitrogen containing polymer materials include: (A) PDADMAC (Mw≈200,000-350,000), (B) PAAm (Mw≈10,000-20,000), (C) PAA (Mw≈1000-2000), (D) PDEE (Mw≈50,000-100,000), (E) PEI (Mw≈20,000-30,000), and (F) PAA-DADMAC (Mw≈200,000-300,000).

FIG. 2 shows a series of RRs of poly-Si films as a function of pH on an IC1000 pad using pH adjusted DI water and aqueous solutions containing 250 ppm of the nitrogen containing polymer materials in accordance with the embodiments.

FIG. 3 shows ζ potentials of 1% silica (dₘₑₐₙ≈50) dispersion in the absence and presence of 250 ppm of each of the nitrogen containing polymer materials in accordance with the embodiments.

FIG. 4 shows ζ potentials of 1% silicon nitride (dₘₑₐₙ≈50) dispersion in the absence and presence of 250 ppm of each of the nitrogen containing polymer materials in accordance with the embodiments.

FIG. 5 shows ζ potentials of poly-Si films in the absence and presence of 250 ppm of each of the nitrogen containing polymer materials in accordance with the embodiments.

FIG. 6 shows ζ potentials of an IC1000 pad in the absence and presence of 250 ppm of each of the nitrogen containing polymer materials in accordance with the embodiments.

FIG. 7A and FIG. 7B show a pair of schematic cross-sectional diagrams illustrating the results of progressive process stages in fabricating a substrate having located and formed thereover a planarized silicon material layer with respect to a silicon containing dielectric material layer in accordance with the embodiments.

### DETAILED DESCRIPTION OF THE EMBODIMENTS

Embodiments include a chemical mechanical planarization (CMP) composition and a chemical mechanical planarization (CMP) method that uses the chemical mechanical planarization (CMP) composition.

Within the embodiments, each of the chemical mechanical planarization (CMP) composition and the chemical mechanical planarization (CMP) method uses a pH adjusted aqueous solution of at least one nitrogen containing material, which may be selected from a particular group of nitrogen containing polymers and their corresponding monomers, absent an abrasive material.

Particular examples within the particular group of nitrogen containing polymers include, but are not limited to: (1) poly(diallyldimethylammonium chloride) (PDADMAC); (2) poly(dimethylamine-co-epichlorohydrin-co-ethylenediamine) (PDEE); (3) poly(allylamine) (PAAm); (4) poly(ethylene imine) (PEI); (5) poly(acrylamide) (PAA); and (6) poly(acrylamide-co-diallydimethyl ammonium chloride) (PAA-DADMAC). Corresponding nitrogen containing monomers include: (1) diallyldimethylammonium chloride; (2) allylamine; and (3) acrylamide. Thus, the particular group of nitrogen containing polymers and corresponding monomers includes ammonium, amine and amide chemical groups. Particularly desirable within the context of the foregoing nitrogen containing polymers are the nitrogen containing polymers designated as PDADMAC, PDEE, PAAm and PEI and their corresponding nitrogen containing monomers diallyldimethylammonium chloride and allylamine.

Within the chemical mechanical planarization composition in accordance with the embodiments the nitrogen containing polymer is present at a concentration from about 5 to about 1000 ppm by weight, more preferably from about 150 to about 350 ppm by weight and most preferably from about 200 to about 300 ppm by weight, where the foregoing ranges may be specific to particular nitrogen containing polymers in accordance with the embodiments.

### 1. Planarization Process Considerations

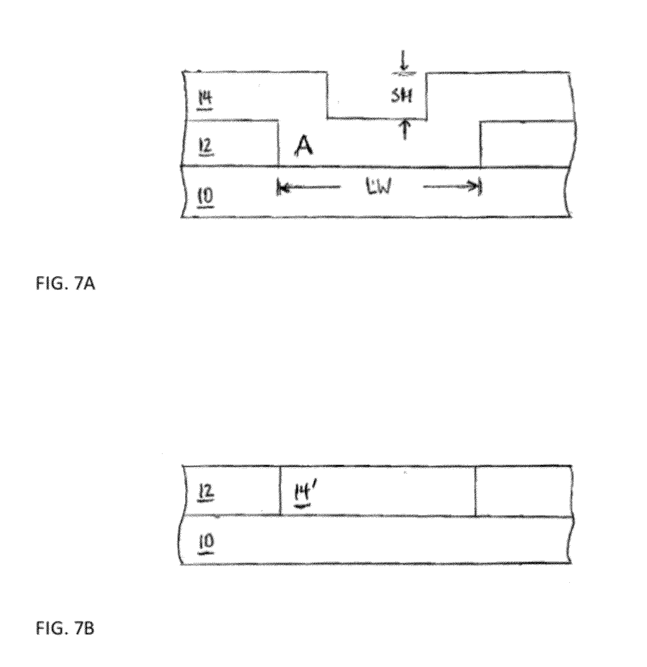

FIG. 7A and FIG. 7B show a plurality of schematic cross-sectional diagrams illustrating the results of progressive process stages in planarizing over a substrate a silicon material layer (i.e., preferably but not limited to a poly-Si material layer) within respect to a silicon containing dielectric material layer (i.e., preferably but not limited to a silicon oxide material layer or a silicon nitride material layer) in accordance with the embodiments. FIG. 7A shows a schematic cross-sectional diagram illustrating the results of an early stage in the processing of the substrate in accordance with the embodiments.

FIG. 7A first shows a substrate 10. A silicon containing dielectric material layer 12 is located and formed over the substrate 10 to provide an aperture A that exposes a portion of the substrate 10. In addition, a silicon material layer 14 is located and formed upon exposed portions of the silicon containing dielectric material layer 12 and the substrate 10 exposed by the aperture A within the silicon containing dielectric material layer 12.

Within the context of the embodiments, the substrate 10 as is illustrated in FIG. 7A may comprise any of several materials from which a substrate is conventionally formed when the substrate is used within an application such as but not limited to a microelectronic application or a microelectromechanical system application. Such materials from which may be comprised the substrate 10 thus include, but are not limited to conductor materials, semiconductor materials and dielectric materials. Typically and preferably, the substrate 10 comprises a semiconductor substrate having located and formed therein and/or thereupon semiconductor devices and/or microelectromechanical system devices as are common in the microelectronic fabrication art and the microelectromechanical system fabrication art.

Within the context of the embodiments, the silicon containing dielectric material layer 12 is intended as comprising a silicon containing dielectric material selected from the group including but not limited to silicon oxide dielectric materials, silicon nitride dielectric materials, silicon carbide dielectric materials, and composites, laminates, blends and alloys of silicon oxide dielectric materials, silicon nitride dielectric materials and silicon carbide dielectric materials. Such alloys of silicon oxide dielectric materials, silicon nitride dielectric materials and silicon carbide dielectric materials may further include, but are not necessarily limited to silicon oxynitride dielectric materials, as well as carbon and hydrogen doped silicon oxide (i.e., SiCOH) dielectric materials. Typically and preferably, the silicon containing dielectric material layer 12 comprises at least one of a silicon oxide dielectric material, a silicon nitride dielectric material, a silicon oxynitride dielectric material and a carbon and hydrogen doped silicon oxide dielectric material having a thickness from about 100 to about 1000 nanometers within the context of a microelectronic substrate, and from about 100 to about 1000 microns within the context of a microelectromechanical system substrate. Similarly, the aperture A linewidth LW is also nanometer sized from about 10 to about 100 nanometers within the context of a microelectronic substrate and micron sized from about 10 to about 100 microns within the context of a microelectromechanical system substrate.

Finally, the silicon material layer 14 may comprise at least one of a monocrystalline silicon material, a polycrystalline silicon material and an amorphous silicon material that may optionally include a dopant within a conventional concentration range. Also considered within the context of the embodiments for the silicon material layer 14 is a germanium doped silicon material layer having a germanium content up to at least about 10 weight percent. The silicon material layer 14 may be formed using any of several methods, including but not limited to chemical vapor deposition methods and physical vapor deposition methods. Typically and preferably, the silicon material layer 14 comprises a polycrystalline silicon material that has a thickness in a nanometer thickness range from about 100 to about 1000 nanometers for a microelectronic substrate and in a micron thickness range from about 100 to about 1000 microns for a microelectromechanical system substrate. As is finally illustrated within the schematic cross-sectional diagram of FIG. 7A, a step height SH of the silicon material layer 14 approximates a thickness of the silicon containing dielectric material layer 12, although such a step height may in fact be considerably greater, including multiple thicknesses of the silicon containing dielectric material layer 12.

As is understood by a person skilled in the art, although FIG. 7A illustrates only a single aperture A accessing the substrate 10 exposed by the silicon containing dielectric material layer 12, the embodiments are not intended to be so limited. Rather the embodiments may include, but are not necessarily limited to, single damascene apertures and dual damascene apertures that may be present within a bi-directional array of multiple apertures located and formed through the silicon containing dielectric material layer 12 and over the substrate 10.

FIG. 7B shows a schematic cross-sectional diagram illustrating the results of further processing of the microelectronic structure or microelectromechanical system structure whose schematic cross-sectional diagram is illustrated in FIG. 7A. FIG. 7B shows the results of planarizing the silicon material layer 14 to provide a silicon material layer 14′. Such planarization of the silicon material layer 14 to provide the silicon material layer 14′ is effected using the chemical mechanical planarization composition in accordance with the embodiments and the chemical mechanical planarization method in accordance with the embodiments, particular aspects of which are discussed in further detail below. Relevant within the context of planarization of the silicon material layer 14 within the schematic cross-sectional diagram of FIG. 7A to provide the silicon material layer 14′ within the schematic cross-sectional diagram of FIG. 7B is an enhanced planarization rate of the silicon material layer 14 (i.e., typically with a removal rate greater than about 300 nanometers per minute and more typically in a range from about 500 to about 600 nanometers per minute) in comparison with the silicon containing dielectric material layer 12 (i.e., typically with a removal rate close to zero). As is discussed further below, the embodiments lead to that favorable result of enhanced planarization rates.

Beyond such an enhanced planarization rate, an abrasive free chemical mechanical planarization composition in accordance with the embodiments and an abrasive free chemical mechanical planarization method in accordance with the embodiments may also provide superior performance within the context of eliminating contaminants, mobile ions, various defects, scratches and structural damage (i.e., such as but not limited to dishing) of planarized features that may be caused by abrasives. In addition, the chemical mechanical planarization composition in accordance with the embodiments and the chemical mechanical planarization method in accordance with the embodiments may generally provide lowered costs.

In general, a chemical mechanical planarization method in accordance with the embodiments also uses: (1) a platen pressure from about 0.2 to about 5 pounds per square inch; (2) a rotation/counter-rotation speed from about 50/50 to about 250/250 revolutions per minute; and (3) a planarization composition flow rate from about 50 to about 300 milli-liters per minute for a 300 millimeter diameter wafer.

### 2. Experimental Methods

2.1. Materials. All the polymers, monomers, silicon nitride particles (dₘₑₐₙ≈50 nm) and pH adjusting agents (HNO₃ and KOH) used here were obtained from Sigma-Aldrich. Colloidal silica particles (dₘₑₐₙ≈50 nm) were supplied by Nyacol Technology. The polishing pads (IC1000) and the diamond-grit conditioner were supplied by Dow Electronic Materials and 3M, respectively. Blanket poly-Si wafers (2000 nm thick, low pressure chemical vapor deposited or LPCVD, at ˜610 C) were obtained from DK Nanotechnology. Thermal oxide (2000 nm thick, grown at ˜900 C) and silicon nitride (500 nm thick, LPCVD at ˜790 C) films grown on silicon substrates were obtained from Montco-Silicon Technologies, Inc. While the poly-Si and silicon nitride films were deposited on an intervening 100 nm thick silicon dioxide layer grown on 8 inch diameter silicon wafers, the thermal oxide was directly grown on the silicon substrates. Each of these 8 inch wafers was cut into several 2 inch diameter pieces, which were then used for polishing.

2.2. Polishing Experiments. The 2 inch diameter wafers were polished for one minute on a CETR polisher at 4 psi down pressure, 90/90 rpm carrier/platen speed and a slurry flow rate of 120 mL/min. The IC 1000 pads (k-groove) used in the polishing experiments were conditioned for one minute using a 4 inch diameter diamond-grit conditioner after every polishing experiment. A Filmetrics interferometer was used to measure the thickness of the different films (oxide, nitride and poly-Si) before and after polishing. The RR of each of these films was determined from the difference between pre- and post-polished film thickness values measured for two different wafers, each at 16 points located across a diameter of the wafer, and then averaged. The standard deviation in the RRs was based on the data for these 32 data points. The pH of all the nitrogen containing polymer (i.e., polycation) or related nitrogen containing monomer solutions was adjusted by adding small amounts of KOH or HNO₃.

2.3. Contact Angle Measurements. A goniometer, assembled on a vibration-free optical table coupled with CAM software (KSV instruments Ltd., Finland) was used to measure the contact angle of a water drop on pre- and post-polished films. Before the measurement, the polished wafer was dried using an air jet. The reported contact angle is the average of 3-4 measurements at three different locations on the wafer (center, middle and edge).

2.4. ζ Potential Measurements. A Matec Applied science model 9800 electro-acoustic analyzer was used to measure the ζ potentials of 1 wt % silica and 1 wt % silicon nitride particles in the absence and presence of each of the polymers or monomers as a function of pH. Nitric acid was used to lower the pH while potassium hydroxide was used to increase the pH of the dispersion. The ζ potentials of a small piece of an IC1000 pad and of a poly-Si film, in the absence and presence of all these polymers, were determined using a ZetaSpin 1.2 apparatus (Zetametrix, Inc., USA). In this technique, the ζ potential is calculated from the streaming potential measured in the vicinity of a rotating disk with aqueous KCl (0.001 M) as the background electrolyte. Because this instrument requires a 1 inch diameter sample with a flat smooth surface, a sample from the IC1000 pad was obtained from the center of the pad, where there are no grooves.

### 3. Results and Discussion

3.1. Polishing Data.

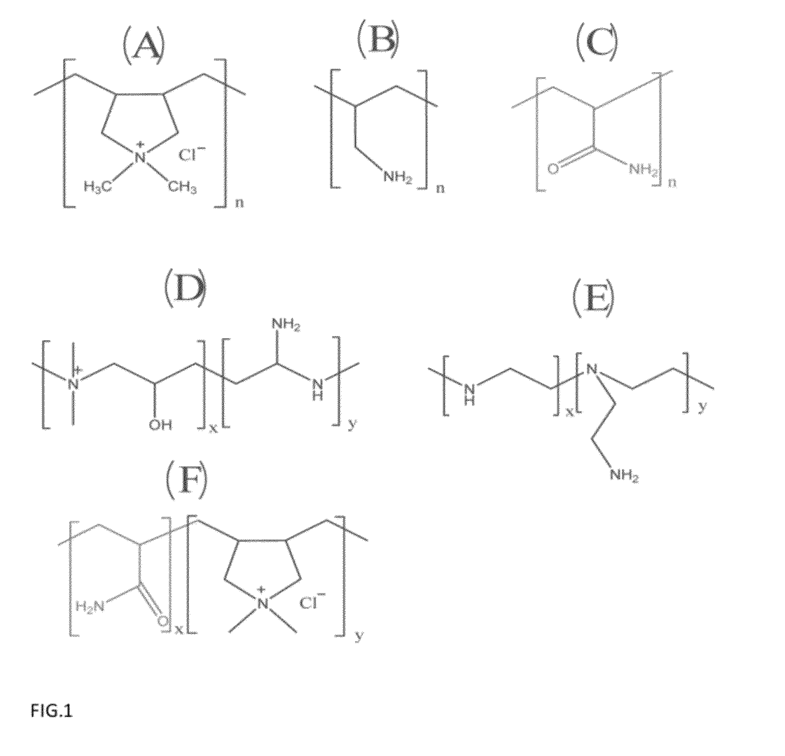

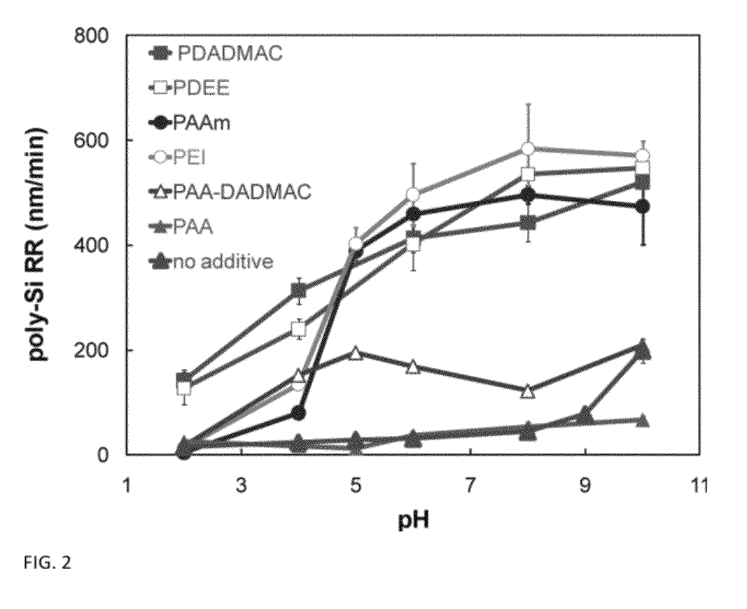

FIG. 2 shows the RRs of poly-Si films obtained using the six different chemical mechanical planarization compositions based upon the six nitrogen containing polymer materials that are illustrated in FIG. 1 (i.e., polycationic-based aqueous solutions), all at 250 ppm concentration, in the pH range 2-10. This concentration was chosen for all the experiments so that the RRs of poly-Si can be compared. Initial observations of RRs of poly-Si films were also made for the nitrogen containing monomers diallyldimethylammonium chloride and allylamine, and although specific data is not reported similar planarization removal rate enhancements of poly-Si films were also observed for those nitrogen containing monomers.

Using only pH-adjusted deionized water, the RRs of poly-Si were low for pH˜</=6 and increased beyond this pH reaching about 200 nm/min at pH 10 due to the increase in the concentration of OH⁻ions which may attack Si—Si bonds and break them. However, 250 ppm PDADMAC aqueous solutions enhance the poly-Si RRs significantly throughout the pH range of 2-10. It is also observed that PDEE aqueous solutions also enhance the poly-Si RRs and, more or less, to a similar extent in the entire pH range. Furthermore, both PAAm and PEI solutions also enhance the poly-Si RRs significantly, but only for pH>/=5. At lower pH values, the RRs dropped and remained lower than those obtained with PDADMAC and PDEE.

In contrast, when PAA solutions were used, the poly-Si RRs did not change much in the pH range 2-8 when compared to those obtained using only pH-adjusted DI water, and, even more interestingly, the poly-Si RR was suppressed to ˜50 nm/min at pH 10, lower than the ˜200 nm/min obtained without PAA. Furthermore, using the copolymer of PAA and PDADMAC, the poly-Si RRs were lower than those obtained with PDADMAC but higher than those obtained with PAA for pH>2.

Unlike the poly-Si RRs, both the oxide and nitride RRs were ˜0 nm/min when polished using pH-adjusted DI water in the pH range 2-10, and they also did not change much throughout the pH range when polished using 250 ppm of aqueous solutions of any of these polymers. These data are not shown.

Thus, it is worth noting that the aqueous abrasive-free solutions of PDADMAC, PDEE, PAAm, and PEI at only 250 ppm concentration can provide a selectivity of poly-Si RR over both oxide and nitride RRs that is useful for the fabrication of FinFET, NAND flash memory and MEMS devices. Before discussing these various RRs and their dependence on pH, it is desirable to understand the adsorption of these nitrogen containing polymer material polycations on the films being polished (poly-Si, oxide and nitride) as well as the polishing pad. One may start with a discussion of the measured ζ potential variations with pH caused by the adsorption of the different nitrogen containing polymer material polycations on these surfaces.

3.2. Adsorption of the Polymers on Silicon Dioxide Surfaces and Its Effect on ζ Potentials.

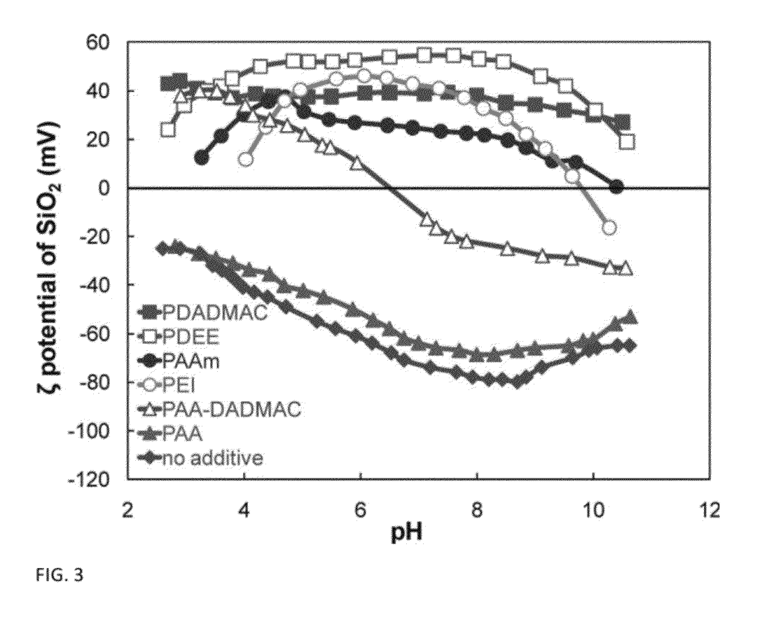

FIG. 3 shows the ζ potentials of aqueous dispersions of 1% silica (dₘₑₐₙ≈50 nm) in the absence and presence of 250 ppm of each of the polymers. In the absence of any additive, the silica surface is negatively charged throughout the pH range 2.5-10. On adding 250 ppm PDADMAC, the charge on the particles was reversed, presumably due to the electrostatic adsorption of the ⁺N(CH3)₃ groups of PDADMAC. The ζ potential remained positive in the entire pH range, with very little dependence on pH, consistent with expected pH-independence of PDADMAC charge density.

In the presence of PDEE, PAAm, or PEI also, the charge of the silica surface was reversed, presumably due to the adsorption of the amine groups of the polymer segments through electrostatic attraction or hydrogen bonding. Indeed, ζ potentials reached even higher positive values with PDEE than those obtained with PDADMAC for 4<pH<10 (i.e., see, FIG. 3). However, ζ potential values declined for lower and higher pH values, and this pH range is polymer specific. For example, in the case of PEI, the higher ζ potential values were for 5<pH<7, and the maximum was observed at pH˜6.

PAA is different from the other polymers since it is essentially nonionic in the pH range 2-10 that is of interest here. Nevertheless, it does apparently adsorb on silica particles as well as on various mineral surfaces, and it was found that the amount adsorbed decreased with increasing pH, presumably due to the hydrolysis of the silanol groups on silica abrasives. Also, it was reported that the adsorption energy is weak. On adding PAA (250 ppm), the negative ζ potentials of the silica surfaces were lowered only slightly for pH>3, presumably because of a shift in the slip boundary layer by the polymer layer adsorbed through hydrogen bonding. This is in contrast to the other positively charged polymers, for which the ζ potential variation is mainly due to the compensation of the silica surface charge by the opposite charge on polymer segments.

On adding 250 ppm of a copolymer of PDADMAC and PAA, the isoelectric point IEP of silica was observed to be between pH 6 and 7. More interestingly, the ζ potential values of silica at low pH are similar to those with PDADMAC. It might be suggested that, at lower pH values, the surface charge densities are the same for particles covered with both PDADMAC and PAA-DADMAC, presumably due to both having the same numbers of adsorbed polymer charges. At higher pH, unlike PDADMAC, PAA-DADMAC does not dissociate the silanol groups further on the silica surface. Hence, less polymer is adsorbed and the ζ potentials may remain low.

3.3. Adsorption of the Polymers on Silicon Nitride Surfaces and Its Effect on ζ Potentials.

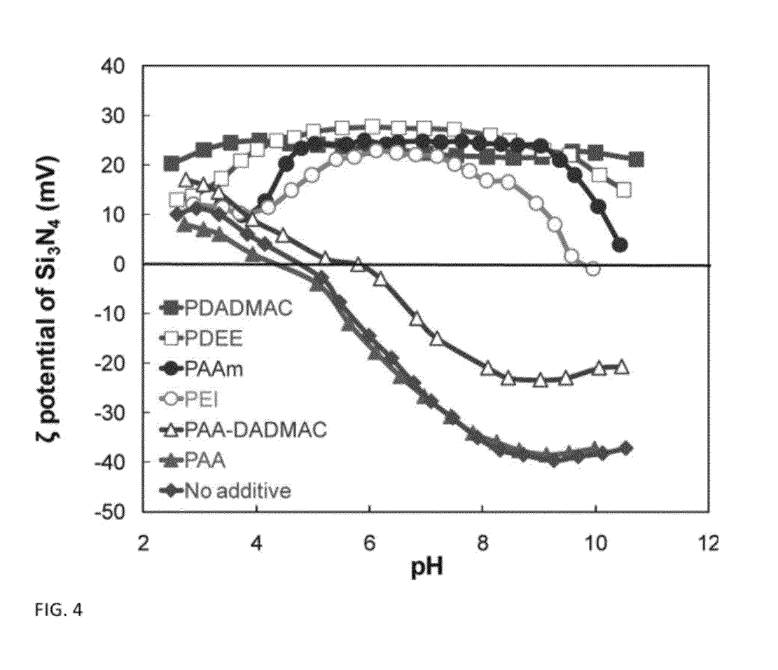

FIG. 4 shows the ζ potentials of 1% silicon nitride (dₘₑₐₙ≈50 nm) based aqueous dispersions in the absence and presence of 250 ppm of each of the nitrogen containing polymers. In the absence of any additive, the IEP of silicon nitride is ˜pH5. Interestingly, in the presence of all these polymers, the behavior of the ζ potentials of the silicon nitride dispersions as a function of pH is very similar to those of silica dispersions except for one noticeable difference. In the presence of PDADMAC or PDEE or PAA-DADMAC, charge uptake seems to occur even below the IEP where electrostatic repulsion would be expected between the positively charged silicon nitride surface and the cationic PDADMAC molecules, indicating the existence of a strong chemical interaction between them.

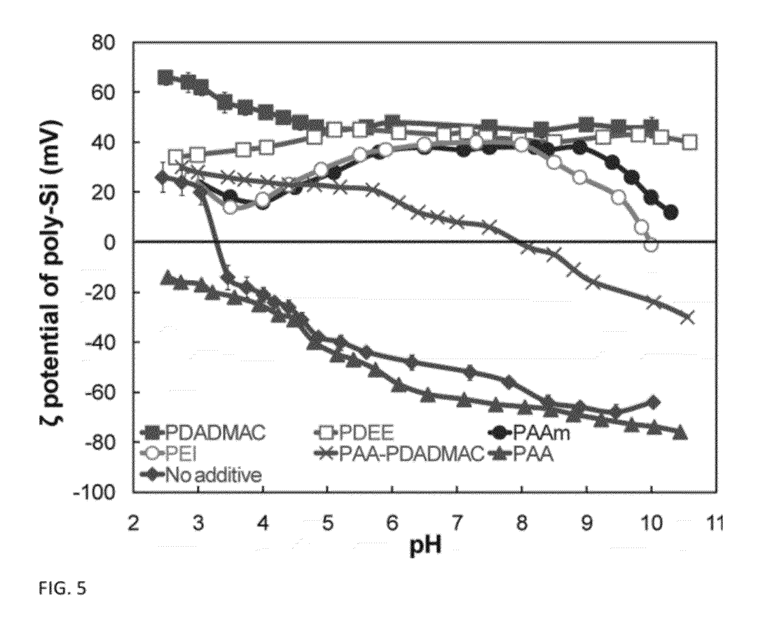

3.4. Adsorption of the Polymers on Poly-Si Films and Its Effect on ζ Potentials. Also considered within the context of the embodiments is the adsorption of the nitrogen containing polymer materials on poly-Si surfaces. The ζ potentials of a poly-Si wafer in the absence and presence of 250 ppm of each of the polymers were measured using the ZetaSpin instrument and the results are shown in FIG. 5. The IEP of poly-Si is 18 3.3. The dependence of the ζ potentials of poly-Si on pH with PDEE, PAAm, PEI, PAA, and PAA-DADMAC is similar to that of silica and silicon nitride surfaces, and similar explanations for the pH-dependence of the ζ potentials above are valid. Also, unlike in the case of silica and silicon nitride particles, hydrophobic-hydrophobic interactions can also affect the adsorption of these polymers on poly-Si surfaces and modify ζ potentials, especially with PDADMAC.

3.5. Adsorption of the Polymers on an IC1000 Pad and Its Effect on ζ Potentials.

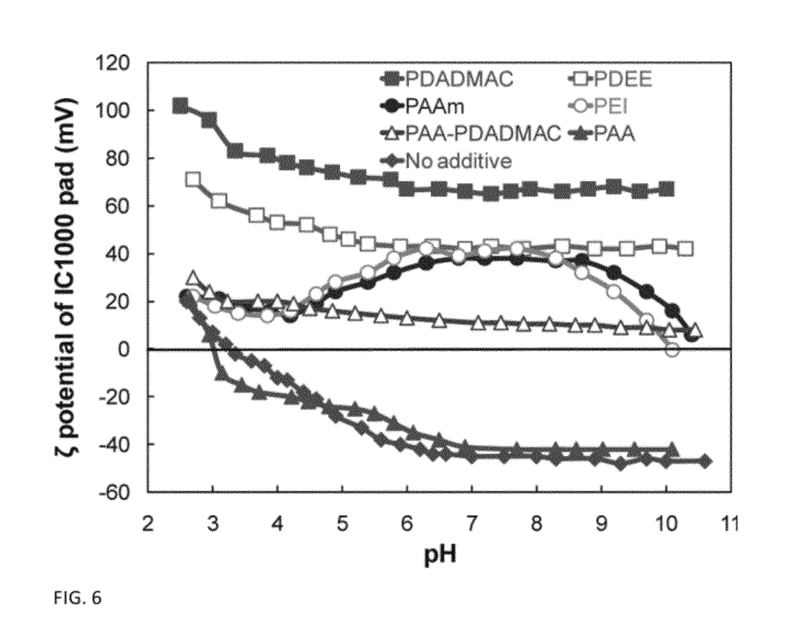

FIG. 6 shows the ζ potentials of an IC1000 pad (i.e., which comprises, and consists essentially of, a polyurethane material), also measured using the ZetaSpin instrument, in the absence and presence of 250 ppm of each of the six polymers. In the absence of any additive, the IC1000 pad had an IEP of ˜3.3 mV. The effect of PDADMAC, PDEE, PAAm, PEI, PAA, and PAA-DADMAC on the ζ potentials of the pad is again very similar to that on oxide, nitride and poly-Si films. Presumably, this is due to interaction of these polymers with the pad surface is through electrostatic and/or hydrogen bonding with hydrolyzable groups (ester, amide, and polyurethanes) on the pad surface being similar to that with the silanol and silanolate groups on the oxide, nitride and poly-Si surfaces. Hence, the pH dependence of the ζ potentials of the pad in the presence of these polymers is also very similar to that of seen with these surfaces. Furthermore, hydrophobic-hydrophobic interactions also augment the electrostatic interaction and/or hydrogen bonding and increase the adsorption strength of these polymers on the IC1000 pad, as in the case of poly-Si.

3.6. Contact Angle Data.

Before polishing, contact angles on both the oxide and nitride films are ˜20°. After polishing with 250 ppm of any of the polymers solutions, the oxide and nitride films became very hydrophilic since the water drop quickly spread out. Similar results were observed with the polished poly-Si films also, even though the contact angle of a water drop on a virgin poly-Si wafer, determined mostly by the Si—H terminal groups on a poly-Si surface, is higher at ˜60°. These results confirm that all the polymers used here interact with the oxide, nitride, and poly-Si surfaces as suggested by ζ potential data.

### 4. POLISHING MECHANISMS

4.1. Proposed Mechanism for Poly-Si Removal in Presence of Aqueous Polymer Solutions and the Role of Polymer Charge Density. Discussed here is a possible overall mechanism of poly-Si removal with the different polymer solutions and then in the next section, the RR variation with pH. A particular model has been developed by Pietsch et al. (see, e.g., (1) Pietsch et al., J. Appl. Phys. 1994, 78, 1650; (2) Pietsch et al., J. Appl. Phys. Lett. 1994, 64, 3115; and (3) Pietsch et al., Surf. Sci. 1995, 33, 395) for removal of silicon that is applicable in the absence of any additive in a silica slurry during a polishing process. Suggested is that OH⁻ in the slurry attacks both Si—H and Si—Si bonds to form Si—OH structures, which polarize the adjacent Si—Si bonds. These polarized Si—Si bonds are attacked and broken by H₂O molecules. Using Fourier transform infrared spectroscopy, one may observe the formation of subsurface oxygen bridges between Si—Si bonds aided by the dissolved oxygen in the ambient slurry. The interface between these suboxide structures and the underlying silicon is also weakened by H₂O molecules enabling their facile removal during polishing after which the process starts all over again.

This particular model was adapted by Dandu et al. (see, e.g., Dandu et al., Colloids Surf., A 2010, 366, 68) to explain the poly-Si RR enhancement upon the addition of a-amines or amino acids. Suggested is that the adsorption of these additives on the poly-Si surfaces further polarizes and weakens the underlying Si—Si and accelerates the formation of suboxide, both leading to high material removal. This particular model may be applied to explain the poly-Si RR enhancement obtained when PDADMAC solutions are used. Using zeta potential measurements, it is proposed that PDADMAC binds to the poly-Si surface and to the IC1000 pad, resulting in a strong bridging interaction between the two surfaces that is mediated by the adsorbed PDADMAC molecules. Based on the measured poly-Si RRs, one may hypothesize that the bridging interaction is stronger than the underlying weakened Si—Si bonds of the poly-Si surface. These weaker bonds are ruptured during polishing, resulting in accelerated material removal.

The ζ potential data and the above description suggest that the other five polymers under consideration also adsorb on the poly-Si film as well as the IC1000 pad. Thus, it is very likely that they also create a similar bridging interaction between the poly-Si and the IC1000 pad surfaces but only PDEE, PEI, and PAAm produced high poly-Si RRs, whereas PAA and PAA-DADMAC produced low poly-Si RRs. Presumably, the strength of the bridging interaction is polymer dependent.

There are several studies (see, e.g., (1) Rojas et al., Langmuir 2002, 18, 1604; (2) Poptoshev et al., Langmuir 2002, 18, 2590; (3) Holmberg et al, Colloids Surf., A 1997, 175, 129; (4) Osterberg et al., Colloid Interface Sci. 2000, 229, 620; and (5) Dahlgren et al., J. Phys. Chem. 1997, 97, 11769) that show that the pull-off force, a related measure, determines the strength of the bridging interaction and is influenced by the charge density of the nitrogen containing polymer material (i.e., polycation). Indeed, this has been measured and investigated theoretically in accordance with Dahlgren et al. with respect to mica surfaces.

For example, using a copolymer of acrylamide (AA) and positively charged 3-(2-ethylpropionamido) propyltrimethylammonium chloride (MAPTAC), Rojas et al. studied the effect of the charge density of the polymer on its adhesion strength on mica surfaces. By changing the ratio of MAPTAC/AA segments of the copolymer, they were able to vary the charge density and observed that the pull-off forces between the mica surfaces decreased as the charge density of the copolymer decreased. For instance, the magnitude of the pull-off force needed to separate the polymer-coated mica surfaces dropped from ˜300 mN/m to only ˜5 mN/m when the polymer was changed from fully charged MAPTAC to a 30% charged 3:7 mixture of MAPTAC and AA. Also, Poptoshev et al. showed that the pull-off forces with branched-PEI molecules are stronger than those with the two linear polymers, polyvinyl amine and poly (2-propionyloxy ethyltrimethylamonium chloride). The latter ones are very similar to PAAm and PDEE, respectively. Evidently, the charge density is a critical parameter.

Therefore, because the charge densities exhibited by each polymer can be categorized in the following sequence PDADMAC=PDEE=PAAm=PEI>PAA-DADMAC>PAA, one might suggest that the pull-off forces, and hence the strength of the nitrogen containing polymer material polycation-mediated bridging interaction between the pad and the films surfaces also follows the same sequence.

The high poly-Si RRs obtained using the high charge density cationic polymers, (PDADMAC, PDEE, PAAm, and PEI) shown in FIG. 2 imply that the pull-off forces, and hence the bridging interaction with these polymers, is stronger than the strength of the underlying polarized Si—Si bonds. When the lower charge density copolymer of PDADMAC and PAA is used, the pull-off forces may decrease and, hence, the removal rates may be lower compared to those with PDADMAC. Finally, PAA induces the lowest pulloff forces among all the polymers since it has the lowest charge density, and hence, produces the lowest RR as illustrated in FIG. 2.

4.2. Variable Effect of pH on Poly-Si Removal with Different Polycations. Both PDADMAC and PDEE have a more or less constant positive charge density in the pH range 2-10 but the increasingly negative charge density of the poly-Si surface with increasing pH (see, e.g., FIG. 5) can result in increased pull-off forces and, hence, increased RRs. Indeed, Holmberg et al. and Osterberg et al. showed that polymer bridging is more favorable when the charge density on the opposite surface increases.

A similar analysis may explain the increasing RRs for pH>1=5 in the case of PEI and PAAm. But for pH<5, Meszaros et al. (Langmuir 2002, 18, 6164) found that the increased degree of protonation of the amine groups in PEI can increase the charge density but also lower the amount of PEI adsorbed on oxide surfaces because of the increased polymer segment-segment repulsion. In view of the similarity between PEI and PAAm, it is very likely that the same arguments apply for PAAm also. Hence, with these two polymers, the lowered amount of adsorption caused by segment-segment repulsion can decrease the number of bridging interactions between poly-Si and IC1000 pad. This in turn can result in a fall in the RRs, even though the pull-off forces are not affected much. In contrast, the quarternized ammonium ions in PDADMAC and PDEE do not protonate and only the charge density, but not the amount adsorbed, influences the RRs.

The RRs of poly-Si with PAA remain low and even lower than that with pH-adjusted DI water, suggesting that PAA adsorption blocks the effects of OH⁺ that cause the increase in the RR with water. Of course, the pull-off forces also are very weak. The dependence of the RRs of poly-Si with PAA-DADMAC on pH is complex and can be attributed to a combination of electrostatic interaction with the poly-Si surface changing from repulsive to attractive at lower pH values and the relatively weak bridging interactions.

4.3. Proposed Mechanism for Oxide and Nitride Removal in Presence of Aqueous Polymer Solutions.

One might consider that even though PDADMAC forms a strong bridging interaction between the IC1000 pad and the oxide or nitride surfaces, the adhesive strength of the polymer on oxide, nitride and IC1000 pad is weaker than the cohesive strength of the oxide and nitride substrates. Hence, during polishing, the polymer-substrate or the polymer-pad bond is broken easily, resulting in no material removal. Based on the RRs and ζ potential data, it appears that the same explanation also applies to polishing with other polymers here. It will be useful to verify this suggestion.

All references, including publications, patent applications, and patents cited herein are hereby incorporated by reference in their entireties to the same extent as if each reference was individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

Therefore, the embodiments are illustrative of the invention rather than limiting of the invention. Revisions and modifications may be made to methods, materials structures and dimensions with respect to a chemical mechanical planarization composition and a chemical mechanical planarization method in accordance with the embodiments while still providing a chemical mechanical planarization composition or a chemical mechanical planarization method in accordance with the invention, further in accordance with the accompanying claims.

What is claimed is:

1. A composition comprising:
an aqueous solution comprising at least one nitrogen containing material selected from the group consisting of poly(diallyldimethylammonium chloride) (PDADMAC), poly(dimethylamine-co-epichlorohydrin-co-ethylenediamine) (PDEE), poly(allylamine) (PAAm) and poly(ethylene imine) (PEI), poly(acrylamide) (PAA) and poly(acrylamide-co-diallydimethyl ammonium chloride) (PAA-DADMAC) nitrogen containing polymers and diallyldimethylammonium chloride, allylamine and acrylamide nitrogen containing monomers at a concentration from about 5 to about 1000 ppm by weight; and
a pH adjusting material, absent an abrasive material.

2. The composition of claim 1 wherein the at least one nitrogen containing material is selected from the group consisting of poly (diallyldimethylammonium chloride) (PDADMAC) and diallyldimethylammonium chloride.

3. The composition of claim 1 wherein the at least one nitrogen containing material is selected from the group consisting of poly(dimethylamine-co-epichlorohydrin-co-ethylenediamine) (PDEE), poly(allylamine) (PAAm) and poly(ethylene imine) (PEI) nitrogen containing polymers, and allylamine nitrogen containing monomer.

4. The composition of claim 1 wherein the at least one nitrogen containing material is selected from the group consisting of poly(acrylamide) (PAA) and poly(acrylamide-co-diallydimethyl ammonium chloride) (PAA-DADMAC) nitrogen containing polymers, and acrylamide nitrogen containing monomer.

5. The composition of claim 1 wherein the pH adjusting material is selected from the group consisting of an acid and a base.

6. The composition of claim 1 wherein the abrasive material is selected from the group consisting of silicon oxide and cerium oxide.

7. The composition of claim 1 wherein the composition comprises a chemical mechanical planarization composition.

8. A planarization method comprising:
positioning a within a chemical mechanical planarization apparatus a substrate including a silicon material layer located over a silicon containing dielectric material layer; and
planarizing within the chemical mechanical planarization apparatus the silicon material layer with respect to the silicon containing dielectric material layer while using a chemical mechanical planarization pad and a chemical mechanical planarization composition comprising:
an aqueous solution comprising at least one nitrogen containing material; and
a pH adjusting material, absent an abrasive material.

9. The method of claim 8 wherein the substrate is selected from the group consisting of a semiconductor substrate and a microelectromechanical substrate.

10. The method of claim 8 wherein the silicon material layer is selected from the group consisting of a monocrystalline silicon material layer, a polycrystalline silicon material layer and an amorphous silicon material layer.

11. The method of claim 8 wherein the silicon containing dielectric material layer comprises a dielectric material selected from the group consisting of silicon oxide dielectric materials, silicon nitride dielectric materials, silicon carbide dielectric materials, carbon and hydrogen doped silicon oxide materials and composites, laminates, blends and alloys of silicon oxide dielectric materials, silicon nitride dielectric materials, silicon carbide dielectric materials and carbon and hydrogen doped silicon oxide materials.

12. The method of claim 8 wherein the at least one nitrogen containing material is selected from the group consisting of poly (diallyldimethylammonium chloride) (PDADMAC) and diallyldimethylammonium chloride.

13. The method of claim 8 wherein the at least one nitrogen containing material is selected from the group consisting of poly(dimethylamine-co-epichlorohydrin-co-ethylenediamine) (PDEE), poly(allylamine) (PAAm), poly(ethylene imine) (PEI) nitrogen containing polymers, and allylamine nitrogen containing monomer.

14. The method of claim 8 wherein the at least one nitrogen containing material is selected from the group consisting of poly(acrylamide) (PAA) and poly(acrylamide-co-diallydimethyl ammonium chloride) (PAA-DADMAC) nitrogen containing polymers, and acrylamide nitrogen containing monomer.

15. The method of claim 8 wherein the at least one nitrogen containing polymer is present in the composition at a concentration from about 5 to about 1000 ppm by weight.

16. A planarization method comprising:
positioning a within a chemical mechanical planarization apparatus a substrate including a polysilicon material layer located over at least one of a silicon oxide layer and a silicon nitride layer; and
planarizing within the chemical mechanical planarization apparatus the polysilicon material layer with respect to the at least one of the silicon oxide layer and the silicon nitride layer while using a chemical mechanical planarization pad and a chemical mechanical planarization composition comprising:
an aqueous solution comprising at least one nitrogen containing material; and
a pH adjusting material, absent an abrasive material.

17. The method of claim 16 wherein the at least one nitrogen containing material is selected from the group consisting of poly (diallyldimethylammonium chloride) (PDADMAC) and diallyldimethylammonium chloride.

18. The method of claim 16 wherein the at least one nitrogen containing material is selected from the group consisting of poly(dimethylamine-co-epichlorohydrin-co-ethylenediamine) (PDEE), poly(allylamine) (PAAm), poly(ethylene imine) (PEI) nitrogen containing polymers, and allylamine nitrogen containing monomer.

19. The method of claim 16 wherein the at least one nitrogen containing material is selected from the group consisting of poly (acrylamide) (PAA) and poly (acrylamide-co-diallydimethyl ammonium chloride) (PAA-DADMAC) nitrogen containing polymers, and acrylamide monomer.

20. The method of claim 16 wherein the at least one nitrogen containing polymer is present in the composition at a concentration from about 1 to about 1000 ppm.
